(19) United States
(12) Patent Application Publication
(10) Pub. No.: US 2014/0319083 A1
(43) Pub. Date: Oct. 30, 2014

(54) Shower Mounted Tablet Computer Holding Device

(71) Applicant: Darrin Stark, Scottsdale, AZ (US)

(72) Inventor: Darrin Stark, Scottsdale, AZ (US)

(21) Appl. No.: 14/263,159

(22) Filed: Apr. 28, 2014

Related U.S. Application Data
(60) Provisional application No. 61/816,378, filed on Apr. 26, 2013.

(51) Int. Cl. A47K 3/28; H05K 7/18; A47F 5/08

(52) U.S. Cl. CPC A47K 3/281; A47F 5/08; H05K 7/18
USPC 211/26

(57) ABSTRACT

Described is a tablet computer holding device that securely holds a portable electronic device, such as a tablet computer, in a desired position on a vertical support surface, particularly while the user is in a shower or bath tub. The device includes an elongated base having a channel extending therealong, and having a hook that is used to suspend the elongated base in a vertical orientation on a shower fixture, such as a shower head, or other similar object. One or more shelves can be positioned on the elongated base in any desired position. Further, a tablet holding assembly can be secured in a desired position on the elongated base and includes several adjustable arms that are used to securely hold the sides of a tablet computer. Additionally, the tablet computer holding assembly is mounted on a joint so that the tablet can be tilted into a desired viewing position.

### CROSS REFERENCE TO RELATED APPLICATION

This application claims the benefit of U.S. Provisional Application No. 61/816,378 filed on Apr. 26, 2013, entitled “Waterproof Electronic Device Housing and Pivoting Mount.” The above identified patent application is herein incorporated by reference in its entirety to provide continuity of disclosure.

### BACKGROUND OF THE INVENTION

1. Field of the Invention

The present invention relates to tablet computer holding devices. More specifically, the present invention relates to a tablet computer holding device that can be mounted on a shower fixture, such as a shower head, or other similar object. The present invention includes an elongated base on which one or more shelves and a tablet computer holding assembly can be positioned. The elongated base is suspended on a shower fixture, such as a shower head, by means of a hook thereon. The tablet computer holding assembly has a plurality of adjustable arms that can be used to securely hold the edges of a tablet computer or portable electronic device of various sizes. Further, the tablet computer holding assembly can be pivoted about a joint so that it can be positioned in a desired angle for viewing by the user.

Many people enjoy taking long showers or baths. Adults may draw a bath in order to relax at the end of the day, and children enjoy playing in the tub. However, adults and children alike may become bored due to a lack of stimulation while spending time in the shower or tub. While adults may find a bath or shower to be relaxing, the adult is unable to perform other tasks or otherwise entertain themselves while in the shower. Further, adults may have to leave the shower in order to perform certain tasks such as checking and sending emails or messages. Thus, a user has limited options for entertaining themselves and engaging in other activities while in the bath or shower.

While taking a bath, some people use a portable electronic device such as a cell phone, smartphone, or tablet computer in order to watch a television show or movie, read a book or newspaper, or perform a variety of other tasks. Such devices may be fitted with any of a variety of waterproof cases, covers, and shields in order to prevent damage thereto from exposure to water. While waterproof cases and cover protect the portable electronic device from water damage, such cases and covers require the user to hold the phone or computer, which may be inconvenient for the user and may prevent the person from feeling relaxed and comfortable. Further, if the user must hold the portable electronic device, the person is unable to use their hands for other purposes such as washing themselves. Conventional bathtubs and showers are not adapted to hold a tablet computer, and a user is likely to be unable to find a place in which the tablet computer can be positioned for viewing. Thus, a device that securely holds a tablet computer, or other similar electronic device, in a desired viewing position so that the user may have full use of his or her hands while taking a bath or shower is desired.

The present invention provides a shower mounted tablet computer holding device adapted to hold a tablet computer, smartphone, or other similar electronic device, in any of a variety of positions so as to allow a user to use their tablet computer while in the bath tub or shower. The term tablet computer as used herein is understood to include any portable electronic device, including but not limited to, tablet computers and smartphones. The present invention comprises an elongated base having a first end with a hook thereon and a second end with an end cap thereon. The hook is adapted to be positioned over a shower fixture, such as the neck of a shower head. The elongated base is suspended by the hook in a vertical configuration, and an elongated channel extends along the length of the elongated base. One or more shelves can be secured at various positions on the elongated base by means of fasteners such as screws, bolts, or magnets, among others. Further, a tablet holding assembly can be secured to the elongated base by means of a joint that allows the tablet holding assembly to tilt upwards, downwards, and from side to side. The tablet holding assembly comprises an arm support that holds a plurality of telescopic arms that are used to hold the edges of a tablet computer so as to securely hold the tablet computer therein. The arms are adjustable so as to be able to securely hold tablet computers of various sizes.

2. Description of the Prior Art

Devices have been disclosed in the prior art that relate to waterproof enclosures for storing various objects while a user is in a shower or bathtub. These include devices that have been patented and published in patent application publications. These devices generally relate to waterproof housings for tablet computers and similar electronic devices. The following is a list of devices deemed most relevant to the present disclosure, which are herein described for the purpose of highlighting and differentiating the unique aspects of the present invention, and further highlighting the drawbacks existing in the prior art.

One such device is U.S. Patent Application Publication Number 2013/0025904 to Berumen, which discloses a pressurized waterproof case for an electronic device. The case is adapted for fluid-tight containment and operation of a touch-screen electronic device. The case may be formed as an enclosure having an open top panel or face that is covered by a flexible, transparent membrane or the like for the operation of the touchscreen device positioned within the case. A system is provided for pressurizing the case and electronic device therein in order to protect the electronic device therein.

Similarly, U.S. Pat. No. 6,879,818 to Wageneck discloses a showerhead with a waterproof enclosure that includes a radio audio source. The device further includes a detachable handle affixed to one side of a showerhead. A waterproof radio speaker, a waterproof on-off radio volume control, and a waterproof radio tuner control are disposed within a waterproof enclosure and are located to facilitate improved reception of the audio sound quality. Thus, Wageneck, similar to Berumen, discloses a device suited for providing a waterproof housing or enclosure for an electronic device, and does not provide an adjustable mount for holding a tablet computer in a shower or bathtub.

U.S. Patent Application Publication Number 2013/0027862 to Rayner describes a housing for an electronic device that protects the device from shocks and liquid damage. The housing includes top and bottom members that seal around the device, and also utilizes a clasping mechanism, such as a locking comb or wedge feature. The clasping mechanism secures the top and bottom members to one another, thereby sealing the housing in a shockproof or watertight manner.

U.S. Pat. No. 5,140,254 to Katzman discloses an accessory for use in a shower that includes a housing having a front, a back, and a fluid passageway extending between the front and back of the housing. The housing is attached to the water outlet so that the fluid passageway registers with the outlet and so that water flowing through the outlet also flows through the fluid passageway. An electrically powered device, such as a radio, is contained within the housing.

Finally, U.S. Pat. No. 4,880,145 to McManus discloses a waterproof assembly for enclosing a variety of articles in a shower. The device includes a backing plate with a mirror mounted between two light enclosures. The device further includes a waterproof radio for use within a shower.

These prior art devices have several known drawbacks. The devices in the prior art are adapted to provide a waterproof enclosure for an object such as an electronic device or tablet computer. The present invention discloses a tablet computer holding device that can be used to hold tablet computers of various sizes, wherein the tablet computer can be covered or enclosed in any of a variety of waterproof enclosures. The devices in the prior art do not provide a tablet computer holding device having a tablet holding assembly that can pivot about a joint so that the tablet can be held in any of a variety of configurations as desired by the user. Further, the prior art does not disclose a tablet computer holding device secured to an elongated base that can be easily secured to a shower fixture, such as the neck of a shower head, in a tool-free manner. Additionally, the prior art does not disclose a tablet computer holding device for use in a shower or bathtub that also includes one or more shelves that can be variously positioned, and on which additional objects can be stored.

In light of the devices disclosed in the prior art, it is submitted that the present invention substantially diverges in design elements from the prior art and consequently it is clear that there is a need in the art for an improvement to existing tablet computer holding devices for use in a shower or bathtub. In this regard the instant invention substantially fulfills these needs.

### SUMMARY OF THE INVENTION

In view of the foregoing disadvantages inherent in the known types of tablet computer holding devices for use in a shower or bathtub now present in the prior art, the present invention provides a new tablet computer holding device wherein the same can be utilized for providing convenience for the user when viewing or using a tablet computer while in a shower or bathtub.

It is therefore an object of the present invention to provide a new and improved shower mounted tablet computer holding device that has all of the advantages of the prior art and none of the disadvantages.

It is another object of the present invention to provide a shower mounted tablet computer holding device that can be easily secured to a shower head and onto a shower wall.

Another object of the present invention is to provide a shower mounted tablet computer holding device that is adjustable so as to hold various sized tablet computer therein.

Yet another object of the present invention is to provide a shower mounted tablet computer holding device comprising a joint that allows the tablet computer to be tilted or pivoted into a desired position for viewing by the user.

Another object of the present invention is to provide a shower mounted tablet holding device that may be readily fabricated from materials that permit relative economy and are commensurate with durability.

Other objects, features and advantages of the present invention will become apparent from the following detailed description taken in conjunction with the accompanying drawings.

### BRIEF DESCRIPTIONS OF THE DRAWINGS

Although the characteristic features of this invention will be particularly pointed out in the claims, the invention itself and manner in which it may be made and used may be better understood after a review of the following description, taken in connection with the accompanying drawings wherein like numeral annotations are provided throughout.

FIG. 1 shows a perspective view of the shower mounted tablet computer holding device of the present invention.

FIG. 2 shows a side view of the shower mounted tablet computer holding device of the present invention.

FIG. 3 shows a close-up view of the tablet holding assembly of the present invention.

FIG. 4 shows a view of the shower mounted tablet computer holding device of the present invention as installed in a shower and as used to hold a tablet therein.

### DETAILED DESCRIPTION OF THE INVENTION

Reference is made herein to the attached drawings. Like reference numerals are used throughout the drawings to depict like or similar elements of the shower mounted tablet computer holding device. For the purposes of presenting a brief and clear description of the present invention, the preferred embodiment will be discussed as used for holding a tablet computer in a shower. The figures are intended for representative purposes only and should not be considered to be limiting in any respect.

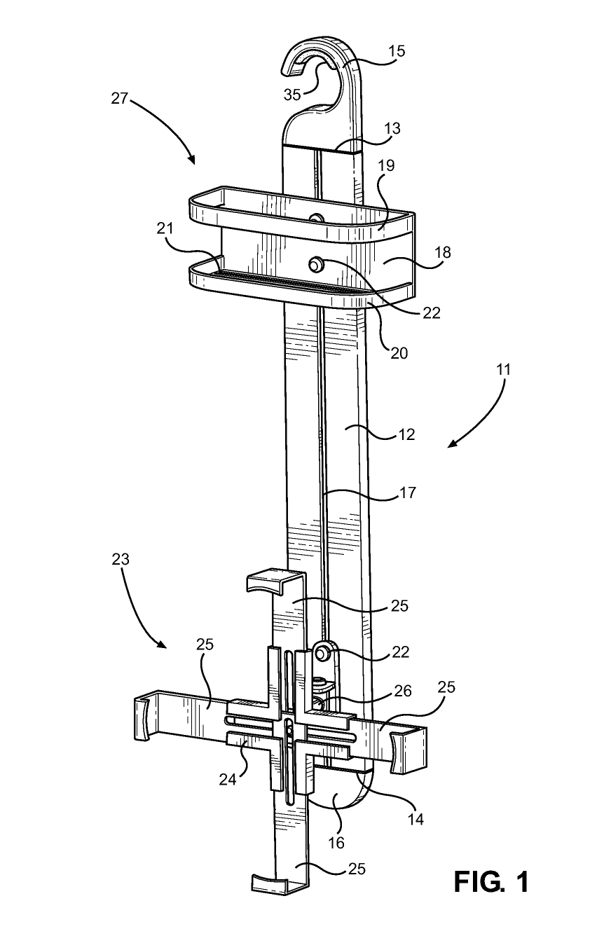

Referring now to FIG. 1, there is shown a perspective view of the shower mounted tablet computer holding device of the present invention. The shower mounted tablet computer holding device 11 comprises an elongated base 12 having a first end 13 opposite a second end 14. The elongated base 12 further comprises an elongated channel 17 disposed on the front face thereof. Preferably, the elongated channel 17 is positioned centrally on the front face of the elongated base 12 and extends between said first end 13 and said second end 14. In use, the back face of the elongated base 12 is adapted to rest against a shower wall or other similar surface. The elongated base 12 preferably comprises a rectangular cross section so that the back face of the elongated base 12 can easily be positioned against a wall. The elongated base 12 may be composed of any suitable lightweight, durable material such as aluminum, and is preferably corrosion resistant.

The first end 13 of the elongated base 12 comprises a hook 15 thereon. The hook 15 comprises a curved upper end that is adapted to be disposed over a shower fixture, such as the neck of a conventional shower head. Alternatively, the hook 15 can be used to hang the tablet computer holding device 11 on a rail or similar structure positioned on a wall or a door. In this way, the elongated base 12 can be suspended by the hook 15 in a vertical, upright orientation. In some embodiments of the present invention, the hook 15 further includes a cushion 35 thereon. The cushion 35 is disposed on the underside of the hook 15, such that the cushion 35 contacts the shower fixture, rather than the hook 15 itself. The cushion 35 comprises a semi-circular shape and is curved similarly to the underside of the hook 15. The cushion 35 is preferably composed of rubber, silicone, or another soft, flexible material that is not adversely affected by exposure to water or moisture. The cushion 35 prevents the metal hook 15 from contacting the metal shower head, so as to prevent the shower head from being scratched thereby. Further, the rubber cushion 35 may help to increase the frictional contact with the shower head, so that the shower mounted tablet holding device 11 does not shift on the shower head. The cushion 35 may be secured to the hook 15 by any suitable fastening means, such as adhesives, or by a fastener such as a screw disposed through said cushion 35 and engaged with the underside of the hook 15.

The second end 14 of the elongated base 12 comprises an end cap 25 thereon. The end cap serves to seal the second end 14 of the elongated base. The end cap 25 is preferably composed of the same material as the elongated base 12. In the illustrated embodiment, the end cap 25 comprises a semi-circular shape so as to provide a rounded edge on the second end 14 of the elongated base 12. The rounded edge eliminates any sharp corners on the elongated base 12. The end cap 25 may be secured to the elongated base 12 by any of a variety of suitable fastening means including by press fitting, or by inserting one or more screws or bolts through the elongated base 12 and through the end cap 25.

One or more shelves 27 can be removably secured to the elongated base 12 in various positions between the first end 13 and second end 14 thereof. Each shelf 27 comprises a back support 18 having an upper end and a lower end. A tray 21 is disposed on the lower end that extends perpendicularly from said back support 18 such that said tray 21 is in a horizontal position. In some embodiments of the present invention, the tray 21 comprises ridges thereon or a high-friction surface such that objects or containers placed on the tray 21 will remain in position, even if the objects are wet and slippery. The tray 21 further comprises an upstanding flange 20 disposed about the perimeter thereof. The flange 20 helps to prevent objects from sliding or falling off of the slide of the shelf 27. The upper end of the shelf 27 comprises a U-shaped rail 19 thereon. The rail 19 extends between a first side and a second side of the back support 18. The rail 19 extends outward, and perpendicular to the back support 18. The rail 19 is preferably the same shape as the flange 20 disposed on the tray 21. In this way, the shelf 27 has a uniform appearance, wherein the flange 20 and rail 19 are substantially similar in structure and dimension. The rail 19 helps to prevent tall objects, such as shampoo and conditioner containers, from falling off of the side of the shelf 27.

The back support 18 of the shelf 27 is adapted to be secured in any of a variety of locations on the elongated base 12 as desired by the user. Further, the shelf 27 may be secured to the elongated base 12 using any suitable fastening means. In some embodiments of the present invention, the shelf 27 comprises one or more magnets thereon, wherein the magnets can be used to magnetically secure the shelf 27 to the elongated base 12. In such embodiments, the elongated base 12 may include magnets thereon for engaging with the magnets on the shelf 27.

In other embodiments of the present invention, the back support 18 may comprise one or more apertures therethrough, suited to receive a fastener such as a screw or bolt. The fastener is positioned within the elongated channel 17 on the elongated base 12 such that the head of the bolt or screw is secured within the channel, and the threaded end extends outward therefrom. The threaded end can then be inserted through the aperture on the shelf 27, which can then be secured using a cap 22 having a threaded interior. By securing the caps 22 tightly onto the threaded ends of one or more fasteners, the shelf 27 can be held securely in a desired position. The cap 22 preferably comprises a rounded exterior to provide a smooth, finished appearance to the fastener. In this way, the user is able to customize the location and number of shelves 27 disposed on the elongated base 12.

The present invention further comprises a tablet holding assembly 23 that can be secured to the elongated base 12 by means of a joint 26. The joint 26 allows the tablet holding assembly 23 to pivot upwards, downwards, and from side to side. The tablet holding assembly 23 comprises an arm support 23 adapted to hold a plurality of arms 25 therein. The arm support 23 comprises channels in which arms 25 can be inserted such that the arms 25 can slide within the channels. The arms 25 have a first end inserted into the arm support 23, and a second end having a flange thereon. The arms 25 are elongated and are substantially rectangular. The flanges extend outward, perpendicular to the arms, and turn inwardly and parallel to the arms at the ends thereof. In this way, the flanges are adapted to extend around the sides of a tablet computer and partially onto the front thereof, so as to securely grasp the tablet computer.

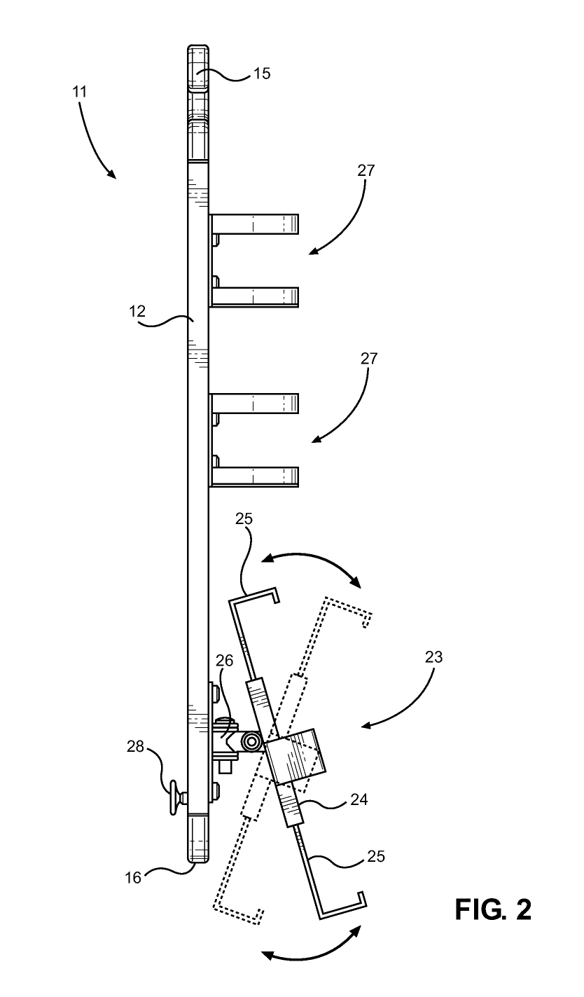

Referring now to FIG. 2, there is shown a side view of the shower mounted tablet computer holding device of the present invention. The tablet holding assembly 23 is secured to the elongated base 12 in a desired position by a joint 26 that allows the tablet holding assembly 23 to pivot upwards or downwards as desired by the user. Further, the joint 26 allows the tablet holding assembly 23 to tilt side to side, or left and right. The joint 26 may comprise a spherical or ball and socket joint, or may include a pair of revolute joints. The joint 26 is secured to the arm support 24 of the tablet holding assembly 23. Once adjusted into a desired configuration, the joint 26 is adapted to retain the tablet holding assembly 23 in the selected position. The joint 26 may be secured to the elongated base 12 and to the tablet holding assembly 23 using fasteners, such as screws or bolts, or by means of one or more magnets.

A user may desire to tilt the tablet holding assembly 23 upwards when the user is standing in the shower and must look downward at the tablet computer held therein. Alternatively, if the user is sitting in a bathtub, the user may wish to tilt the tablet holding assembly 23 downwards so that the user may look up at the tablet computer. When the tablet holding assembly 23 is tilted downwards, the flanges on the ends of the arms 25 prevent the tablet computer from falling out of the tablet holding assembly 23. The arms 25 extend around the sides of the tablet computer, and the flanges extend onto the front surface of the tablet computer so as to secure the tablet computer. Further, when the plurality of arms 25 are positioned snugly against the sides of the tablet computer, the tension provided by the arms 25 also helps to prevent the tablet computer from falling off of the tablet holding assembly 23.

The elongated based base 12 comprises one or more fasteners, such as suction cups 28, on the back face thereof. The fasteners are used to secure the second end of the elongated base 12 to the shower wall or similar support surface. In this way, the hook 15 on the first end of the elongated base 12 is secured to a shower fixture, such as a shower head, and the second end of the elongated based 12 is secured to a shower wall by means of the fasteners. In this way, the elongated base 12 is held firmly in position.

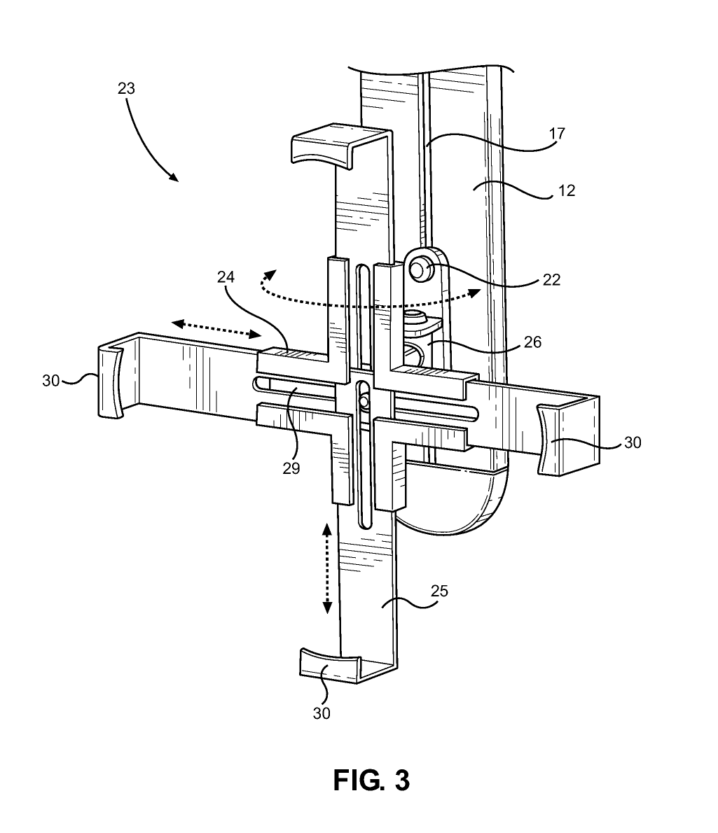

Referring now to FIG. 3, there is shown a close-up view of the tablet holding assembly of the present invention. In addition to allowing the tablet holding assembly 23 to tilt upwards and downwards, the tablet holding assembly 23 is adapted to rotate about the joint 26 from side to side, providing the user with additional options for how to position the tablet computer. The tablet holding assembly 23 comprises an arm support 24 having one or more channels, each adapted to receive an arm 25 therein.

Each arm 25 comprises a first end and a second end, wherein said first end is inserted into a channel of said arm support 24, and the second end comprises a flange 30 thereon. The arms 25 are telescopic and are able to extend from and collapse into the channels of the arm support 24. In this way, the arms 25 can be adjusted so as to provide a secure fit for tablets of various sizes. In some embodiments of the present invention, the arms 25 are adjusted and secured in position by means of engaging a fastener with an elongated slot 29 disposed on each arm 25. Thus, once an arm 25 is configured in a desired position, a fastener, such as a screw, can be inserted in a desired positioned in the elongated slot 29 and secured to the arm support 24 so that the arm 25 is held in the selected position. In this way, the tablet holding assembly 23 can be adjusted so as to suit any of a variety of tablets and similar electronic devices.

In the illustrated embodiment, the arm support 24 comprises a cross shape, wherein four arms 25 are positioned at right angles relative to one another. Two arms are positioned vertically, wherein one arm 25 is adapted to secure the bottom edge of a tablet computer, and the second arm 25 is adapted to secure the top edge of the tablet computer. Two additional arms 25 are positioned horizontally, and are used to hold the side edges of the tablet computer. Thus, each arm 25 can be independently adjusted so as to be positioned flush against an edge of a tablet computer. In this way, the tablet computer can be supported between the arms 25 by tension created by engagement of the arms with the edges of the tablet computer. For additional protection, the arms 25 comprise outwardly extending flanges 30 having inwardly turned ends that extend onto the front surface of the tablet. Thus, the flanges 30 grasp the front of the tablet to prevent the tablet from falling off of the tablet holding assembly 23.

In alternate embodiments of the present invention, the arm support 23 may comprise a different number of channels adapted to hold a different number of arms 25. In some embodiments, the arm support 24 is T-shaped, and includes only three channels adapted to receive three arms 25 therein. In such an embodiment, the arm support 24 comprises two horizontal arms and one vertical arm adapted to hold the bottom edge of a tablet computer. In this way, the arms 25 support the bottom and sides of the tablet computer, while the upper edge of the tablet is left exposed. This allows for a user to easily insert a tablet computer into the tablet holding assembly, and eliminates the need for a user to adjust and secure an upper arm of the assembly.

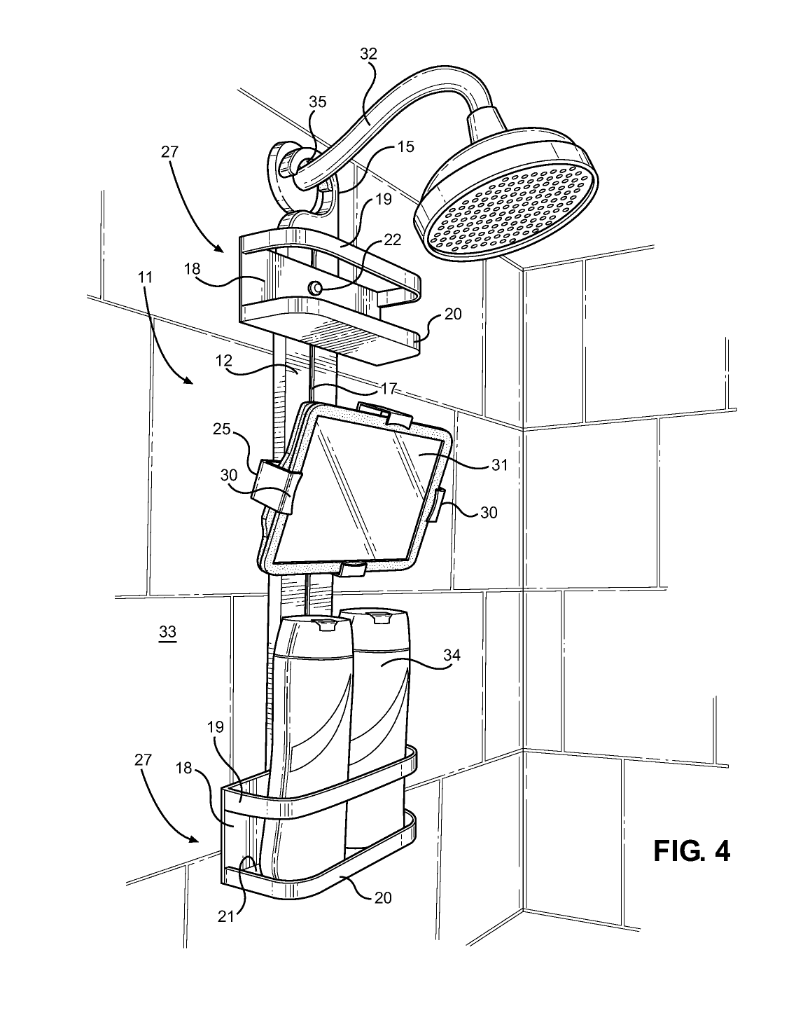

Referring now to FIG. 4, there is shown a view of the shower mounted tablet computer holding device as installed in a shower and as used to hold a tablet computer. In operation, the hook 15 of the device 11 is disposed around the neck of a shower head 32 with the cushion 35 positioned against the neck of the shower head 32 in order to suspend the elongated base 12 in a vertical orientation. In this configuration, the back surface of the elongated base 12 rests adjacent to the shower wall 33.

One or more shelves 27 are disposed on the elongated base 12 and are used to hold and store various containers and objects 34, such as shampoo bottles and soap. Tall objects such as shampoo bottles are positioned on the tray 21 and the sides of the shampoo bottles are supported by the rail 19 so that the objects are prevented from falling off of the shelf 27. The shelves 27 can be positioned in a variety of locations along the elongated base 12 as desired by the user. The back support 18 of the shelf 27 is secured to the elongated base 12 by means of fasteners such as screws, bolts, or magnets, among others. Where screws or bolts are used, such fasteners may be further secured using a threaded cap 22.

A tablet computer 31 is secured within the tablet holding assembly and is held in place by a plurality of arms 25 having flanges 30 on the ends thereof. The arms 25 are adjusted so as to be positioned firmly against the edges of the tablet computer 31. The arms 25 in the illustrated embodiment hold each edge of the tablet computer 31. The flanges 30 extend onto the front surface of the tablet computer 31 so as to hold the tablet computer 31 securely in place. The user is able to adjust the viewing angle of the tablet computer 31 by moving the tablet holding assembly about the joint. The user can simply grasp the tablet computer and tilt the tablet computer into the desired position, and the joint is adapted to maintain the tablet computer in the desired configuration.

It is therefore submitted that the instant invention has been shown and described in what is considered to be the most practical and preferred embodiments. It is recognized, however, that departures may be made within the scope of the invention and that obvious modifications will occur to a person skilled in the art. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

I claim:

1. A shower mounted tablet computer holding device, comprising
an elongated base having a first end, a second end, a front face, and a back face;
wherein an elongated channel extends between said first end to said second end along said front face of said elongated base;
a hook disposed on said first end of said elongated base;
a tablet computer holding assembly secured to said elongated base by means of a joint adapted to allow said tablet computer holding assembly to tilt upwards, downwards, and from side to side.

2. The shower mounted tablet computer holding device of claim 1, wherein
said elongated base comprises a rectangular cross section.

3. The shower mounted tablet computer holding device of claim 1, wherein
said back face of said elongated base comprises one or more suction cups thereon, adapted to secure said elongated base to a shower wall.

4. The shower mounted tablet computer holding device of claim 1, further comprising at least one shelf removably secured to said elongated base.

5. The shower mounted tablet computer holding device of claim 4, wherein
said shelf comprises a back support having an upper end and a lower end, and a tray secured to said lower end, wherein said tray extends perpendicularly from said back support.

6. The shower mounted tablet computer holding device of claim 1, wherein said tablet computer holding assembly comprises:
an arm support secured to said joint, wherein said arm support comprises a plurality of channels, wherein each channel is adapted to accept an arm therein;
a plurality of arms adapted to be inserted into said channels such that said arms can extend from or collapse into said channel.

7. The shower mounted tablet computer holding device of claim 6, wherein
each of said plurality of arms has a first end and second end;
wherein said first end is inserted into one of said channels on said arm support;
wherein said second end comprises a flange thereon that extends perpendicularly to said arm;
wherein an end of said flange is turned inward and parallel to said arm.

8. The shower mounted tablet computer holding device of claim 6, wherein
said arm support comprises four channels arranged such that said channels are disposed perpendicularly to one another.

9. The shower mounted tablet computer holding device of claim 6, wherein
said arm support comprises three channels arranged in a T-shape, wherein two of said channels are disposed in a horizontal orientation, and wherein one channel is disposed in a vertical orientation.

10. The shower mounted tablet computer holding device of claim 1, wherein
said second end of said elongated base comprises an end cap thereon.

11. The shower mounted tablet computer holding device of claim 1, wherein
said hook comprises a cushion on an underside thereof, adapted to engage with a shower fixture.

12. The shower mounted tablet computer holding device of claim 1, wherein
said joint comprises a ball and socket joint.

13. The shower mounted tablet computer holding device of claim 1, wherein
said joint comprises a pair of revolute joints.

14. The shower mounted tablet computer holding device of claim 4, wherein
said shelf comprises an aperture therethrough adapted to receive a fastener;
wherein a fastener is disposed within said elongated channel and extends therefrom;
wherein said fastener extends through said aperture;
wherein said shelf is secured on said fastener by means of a cap having a threaded interior engaged with said fastener.
